(19) United States
(12) Patent Application Publication
(10) Pub. No.: US 2019/0270644 A1
(43) Pub. Date: Sep. 5, 2019

(54) METHOD FOR PRODUCING A SUSPENSION OF GRAPHENE PARTICLES AND CORRESPONDING SUSPENSION

(71) Applicants: INSTITUT QUÍMIC DE SARRIÀ CETS FUNDACIÓ PRIVADA, Barcelona (ES); UNIVERSITAT RAMON LLULL, FUNDACIÓ PRIVADA, Barcelona (ES)

(72) Inventors: CARLES COLOMINAS GUARDIA, Barcelona (ES); BERNAT SEMPERE NOMEN, Barcelona (ES)

(21) Appl. No.: 16/343,643

(22) PCT Filed: Oct. 19, 2017
(86) PCT No.: PCT/ES2017/070697

§ 371 Date: Apr. 19, 2019

(30) Foreign Application Priority Data
Oct. 20, 2016 (ES) P201631357

(51) Int. Cl. C01B 32/194; C01B 32/186; C23C 16/26; C23C 16/56

(52) U.S. Cl. CPC C01B 32/194; C01B 32/186; C23C 16/26; C01P 2004/03; C01B 2204/02; C01P 2004/62; C23C 16/56

(57) ABSTRACT

The invention relates to a method of producing a suspension of graphene particles and the corresponding suspension. The method of producing a suspension of graphene particles comprises the steps of:
[a] depositing carbon on a substrate by means of CVD, where graphene particles are formed on the substrate partially covering it,
[b] interrupting the deposition of carbon on the substrate before the surface of the substrate coated with graphene is more than 85% of the total surface of the substrate,
[c] immersing the substrate in a liquid, and
[d] separating the graphene particles from the substrate such that they are suspended in the liquid.

At least 50% of the graphene particles in the suspension are monolayer particles.

### CROSS-REFERENCE TO RELATED APPLICATIONS

This application is a national stage entry of International Patent Application No. PCT/ES2017/070697 (published as WO 2018/073478 A1), filed on Oct. 19, 2017, titled “Method for Producing a Suspension of Graphene Particles and Corresponding Suspension,” which claims priority from Spanish Patent Application No. P2016/31357, filed on Oct. 20, 2016, titled “Method for Producing a Suspension of Graphene Particles and Corresponding Suspension,” the disclosures of which are incorporated herein by reference in their entirety.

### FIELD OF THE INVENTION

The invention relates to a method of producing a suspension of graphene particles. The invention also relates to a suspension of graphene particles.

Graphene is a monolayer of pure carbon atoms arranged in a regular hexagonal pattern. It is a transparent material with high electrical and thermal conductivity, as well as high mechanical strength (about 200 times greater than that of steel).

### STATE OF THE ART

The two most common production methods are by means of exfoliation and CVD (Chemical Vapor Deposition).

Exfoliation methods basically consist of exfoliating natural graphite. Exfoliation can be done using mechanical means (by using adhesive tapes separating layers from a graphite block) or in a liquid medium (by means of providing ultrasound energy, milling, etc., and adding solvents). Natural graphite exfoliation methods generally allow obtaining small graphene particles in a large amount which are not really particles having a single layer, but rather particles having more than one layer. Therefore they have limited applications.

In CVD methods, graphene is grown on a metal substrate which acts as a catalyst. The substrate can be, for example, Cu, Ni, Rh, Ir, etc. This technique allows obtaining relatively large surfaces, but the graphene that is obtained is a polycrystalline graphene with defects in its crystalline structure. After generating the layer on the substrate, there is a transfer step for transferring the layer of the substrate to the final surface that is to be coated with graphene. In a known transfer step, the graphene layer is coated with a polymeric material. The substrate is then removed by dissolving it in a suitable solvent (for example, an acid or an aqueous ferric chloride solution), the sheet of polymeric material with the graphene is applied on the final surface and the polymeric material is removed. This transfer method includes a plurality of steps which can furthermore contaminate the graphene and/or cause imperfections in the graphene, such as breakages, folds, etc. An alternative to dissolving the substrate basically consists of generating hydrogen bubbles in the substrate by means of an electrolysis process, which causes the detachment of the sheet with the polymeric material and the graphene layer.

Graphene is a relatively new product and a plurality of its applications, both as particles and as layers having larger or smaller dimensions, such as, for example, in batteries, conductive paints and dyes, anti-corrosion coatings, OLED (organic LED), lubricants, flexible touch screens, etc., is currently under research. It is therefore necessary to provide methods of producing high quality graphene particles (understood in many different ways: higher percentage of monolayer graphene, greater monocrystallinity, greater homogeneity with respect to properties, lower chemical contamination, etc.).

### DESCRIPTION OF THE INVENTION

The object of the invention is to overcome these drawbacks. This object is achieved by means of a method of producing a suspension of graphene particles characterized in that it comprises the steps of:

[a] depositing carbon on a substrate by means of CVD, where graphene particles are formed on the substrate partially covering it,

[b] interrupting the deposition of carbon on the substrate before the surface of the substrate coated with graphene is more than 85% of the total surface of the substrate, preferably before the surface of the substrate coated with graphene is more than 75% of the total surface of the substrate.

[c] immersing the substrate in a liquid, and

[d] separating the graphene particles from the substrate such that they are suspended in the liquid.

Deposition generally starts in nuclei from each of which a single-crystal graphene grows. As they grow, there will come a time when these crystals come into contact with their neighboring crystals, coalescing and forming polycrystalline particles. Likewise, as the coating process progresses, the growth of a second layer on the already deposited layer will start at certain points. The basic concept of the invention consists of interrupting the substrate coating method when the substrate is coated with a plurality of graphene particles, each of them generated from a grain growth nucleus but in an “initial phase” of coating. A plurality of advantages is thereby achieved: the particles are mostly monolayer particles, the particles are mostly monocrystalline particles, defects in the crystalline structure are minimized, the method is, mechanically speaking, not very aggressive so defects such as breakages, etc., are minimized.

In the known substrate coating methods, the objective is to always obtain a continuous graphene layer, where the existence of non-coated regions is a defect that must be minimized. In the method according to the invention, the strategy is exactly the opposite: to try to prevent as much as possible the coalescing of grain growth nuclei, such that the graphene that is obtained is a plurality of particles that are independent of one another.

When reference is made to the total surface of the substrate, it must be understood as the total “useful” surface of the substrate, i.e., the surface subjected to the coating process and from which the generated particles are to be obtained.

Preferably, the substrate is a metal substrate, preferably a Cu substrate, or other metal that does not exhibit problems with hardening during the coating process. Alternatively, the substrate can have a non-metal base and a metal coating, preferably a Cu coating. Advantageously, the Cu is electropolished Cu so that the substrate has a low roughness.

The substrate can be in various forms: it can be a sheet, a wire, foam, a plurality of particles, etc.

An electrolysis causing the detachment of hydrogen on the surface of the Cu is preferably performed in step [d], such that graphene particles on the Cu are suspended in said liquid. Alternatively, the Cu can be dissolved in step [d], such that the graphene particles on the Cu are suspended in the liquid.

As mentioned above, the basic concept of the invention is to interrupt the deposition step before it has progressed “too far”. As the deposition step progresses, various processes take place more or less in parallel:

a graphene crystal grows around each growth nucleus,

adjacent graphene crystals grow until they come into contact with one another, forming a polycrystalline particle,

as the graphene crystals group together, there are fewer and fewer independent particles, until finally all the particles are bound together. Coalescence is complete at this point, even though the graphene layer can still exhibit discontinuities (uncoated regions or “holes”)

finally, all the holes of the graphene layer are coated and a completely continuous layer is obtained,

in parallel, deposition of a second graphene layer on the already deposited layer starts in some particles.

There are therefore many ways to define the moment in which the deposition step must be interrupted, depending on the physical phenomenon being considered. The purpose of step [b] can therefore be characterized by many preferred ways:

The interruption takes place before more than 30% of the graphene particles are polycrystalline particles, preferably before more than 20% of the graphene particles are polycrystalline particles.

The interruption takes place before more than 50% of the generated graphene surface is a multilayer surface.

The interruption takes place before the particles completely coalesce.

Advantageously, the method according to the invention comprises a step of recrystallizing the substrate or the metal coating before the deposition step and/or comprises a step of reducing surface oxides before the deposition step.

The deposition step is preferably performed in a CH₄ and H₂ atmosphere, with a CH₄ content comprised between 10% and 60%, for a time comprised between 1 and 60 minutes, at a pressure comprised between 0.01 and 1000 mbar, preferably between 0.01 and 10 mbar, and at a temperature comprised between 900° C. and 1060° C.

Advantageously, step [b] of interrupting the deposition comprises a cooling step in which the partially coated substrate is cooled at a temperature less than 600° C. in a time less than 30 minutes, and preferably in a time less than 120 seconds. Indeed, as mentioned above, the basic concept of the invention lies in interrupting the deposition step before it progresses “too far.” Given that the reaction takes place with the substrate at a high temperature, it is suitable to rapidly cool the substrate when interrupting the deposition step so that the interruption occurs at exactly the desired time.

Another object of the invention relates to a suspension of graphene particles characterized in that at least 50% of the graphene particles are monolayer particles, and preferably at least 70% of the graphene particles are monolayer particles. Indeed, a suspension of this type is new as it cannot be obtained using conventional methods. The mean particle size is preferably greater than 700 nm. In relation to this feature, it must be taken into account that the particles have a certain tendency to cluster together, so it is possible for smaller particles to cluster together until forming clusters of more than 700 nm. However, in the present case reference is made to the mean size of non-clustered particles.

### BRIEF DESCRIPTION OF THE DRAWINGS

Other advantages and features of the invention can be seen from the following description in which the preferred embodiment/embodiments of the invention are described in reference to the attached drawings in a non-limiting manner. In the drawings:

FIG. 1 shows a diagram of an installation for depositing graphene by means of CVD.

FIGS. 2 to 5 show the SEM (Scanning Electron Microscope) micrographs of the graphene deposited on 4 Cu substrates at 950° C. and 10% methane: sheet, wire, particles and foam, respectively.

FIGS. 6 to 9 show the SEM micrographs of the graphene deposited on 4 Cu substrates at 950° C. and 30% methane: sheet, wire, particles and foam, respectively.

FIG. 10 shows the Tyndall effect, graphene-free solution.

FIGS. 11 to 13 show the Tyndall effect, solutions with graphene in suspension.

FIGS. 14 and 15 show SEM micrographs of a Cu wire before and after the separation step.

### DETAILED DESCRIPTION OF SEVERAL EMBODIMENTS OF THE INVENTION

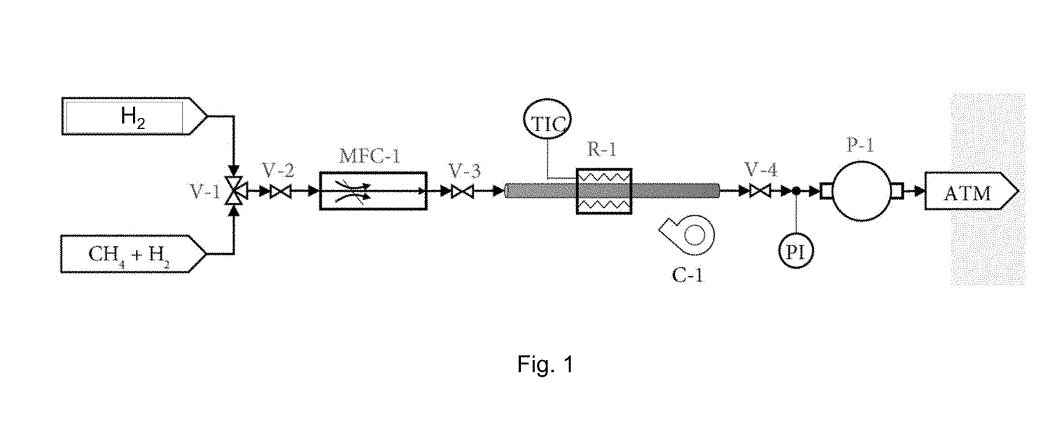

FIG. 1 shows a diagram of the installation for depositing graphene used in the present invention. It has a hydrogen (H₂) source and a source of methane and hydrogen (CH₄+H₂) mixtures which are connected to a 3-way valve V-1 and feed a reactor R-1. A mass flow controller MFC-1, with its corresponding ball valves V-2 and V-3, is located at the inlet of the reactor R-1. The reactor E-1 has a temperature indicator and controller TIC. A globe valve V-4, a pressure sensor PI and a vacuum pump P-1 discharging suctioned gases into the atmosphere ATM are located at the outlet of the reactor R-1. The installation also has cooling means schematically depicted as C-1.

### EXAMPLES

Graphene was deposited by means of CVD on different Cu substrates: sheet, wire, particles and foam under the following conditions:

Time: 10 minutes

Temperature: 950° C.

Pressure: 2.5-2.6 mbar

Rapid heating and cooling. Specifically, the partially coated substrate was cooled to 700° C. in 10 seconds and to 400° C. in 30 seconds after the indicated reaction time in both cases.

In all cases, the substrates were washed with ultrasounds and electropolished in a 50% (v/v) aqueous phosphoric acid solution at 2 V (volts) for a period between about 5 and 20 minutes (6 minutes for wire, 8 minutes for sheet and foam, 15 minutes for particles).

In all cases, the substrates were subjected to treatment in an H₂ atmosphere at 0.7 mbar and 950° C. for 15 minutes before starting the deposition step. This treatment aims to eliminate the surface oxide layer and to grow Cu grains.

The atmosphere of the reactor is changed for an atmosphere that is a mixture of hydrogen and methane.

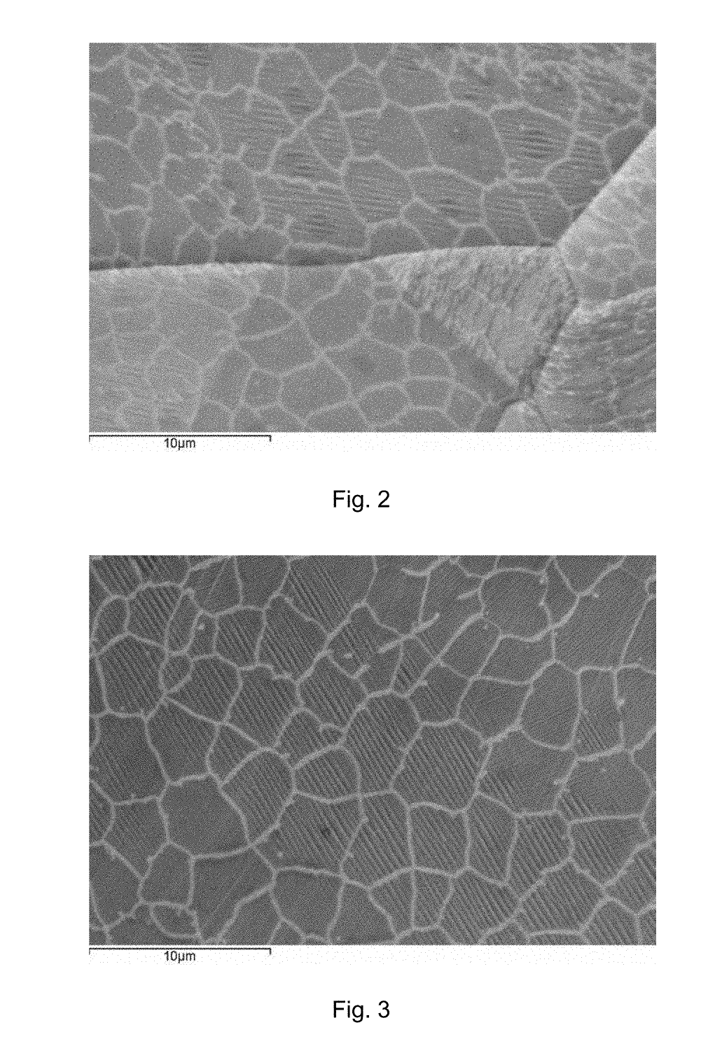

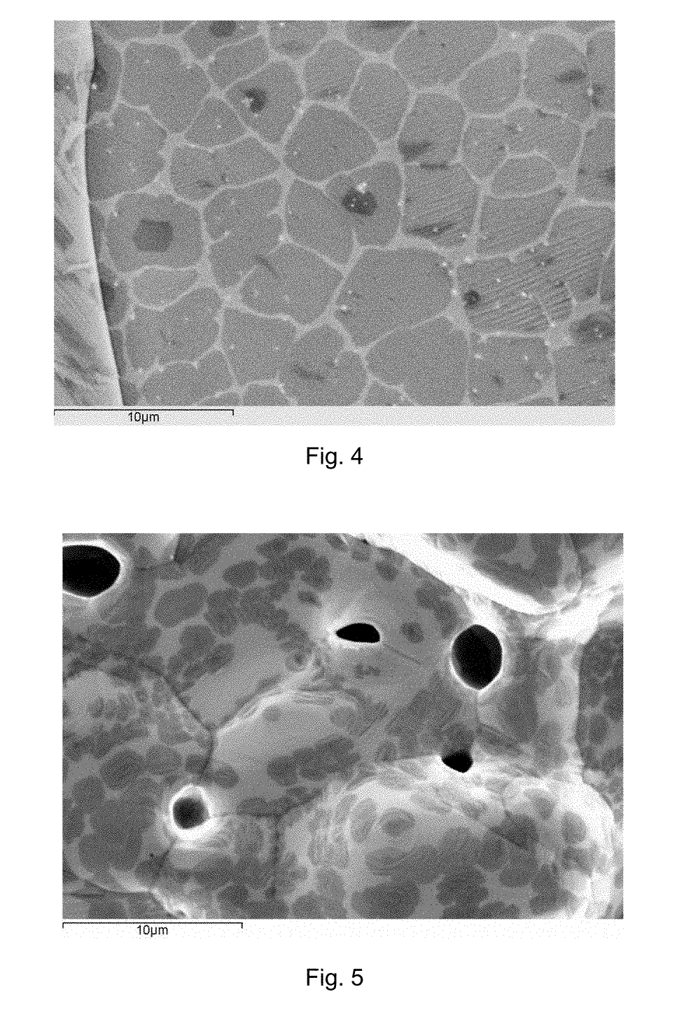

The methane concentration in a first test group was 10% (10% methane, 90% hydrogen). The results are shown in FIGS. 2 to 5. It can be seen that the foam substrate yields the worst results.

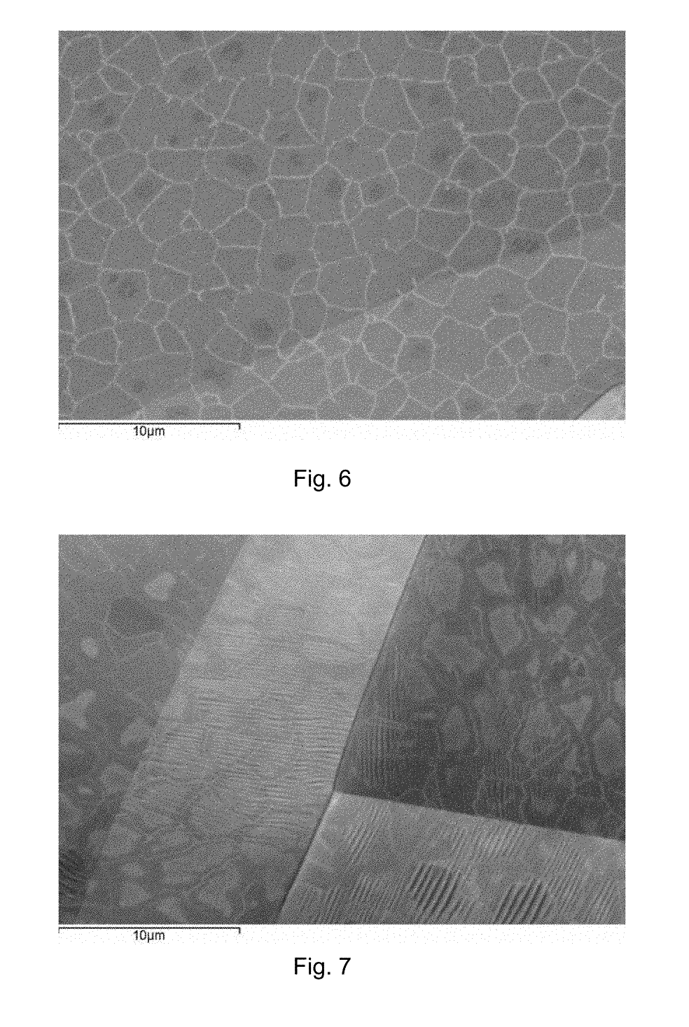

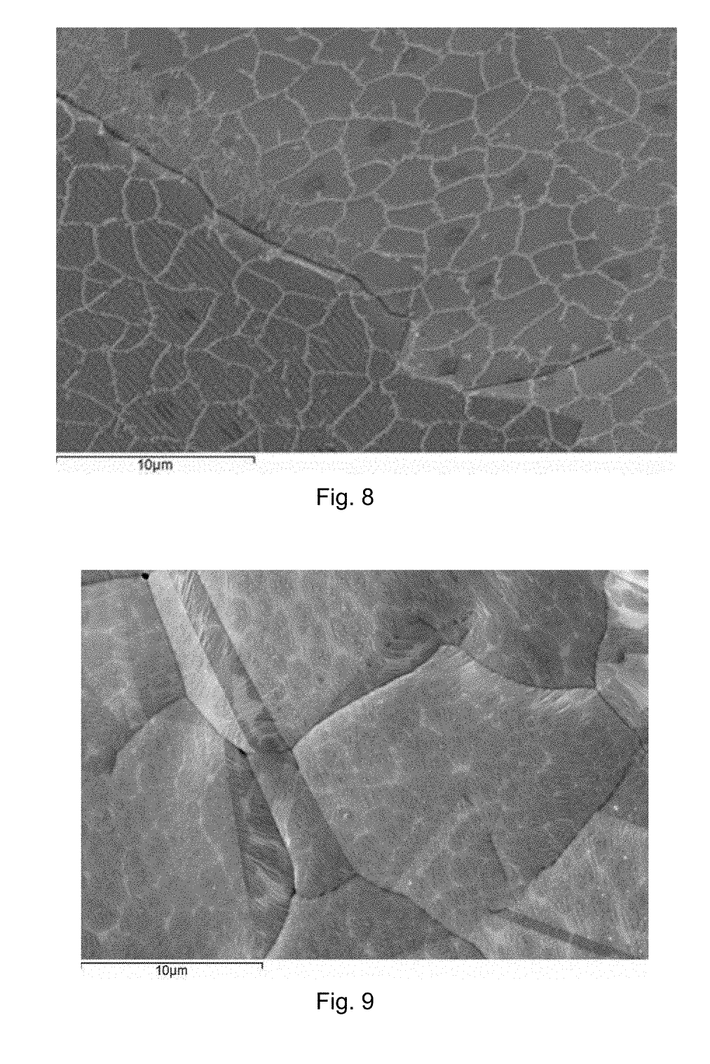

The methane concentration in a second test group was 30% (the rest being hydrogen). The results are shown in FIGS. 6 to 9. It can be seen that the graphene particles are closer together, but they do not completely coalesce. It can also be seen that there is more nucleation and that the particles are smaller. The results obtained in the 4 substrates are the same.

Preparation of Suspensions:

Samples of graphene prepared on a copper wire were subjected to the following electrolytic process:
Solution: MilliQ® water and 0.25 M ammonium nitrate (NH₄NO₃) to attain a conductivity of 11.2 mS
Electrochemical assembly:
   Anode: substrate partially coated with graphene
   Ti cathode
5 V are applied for 5 minutes
The suspensions are analyzed with a laser and the Tyndall effect (light scattering due to the presence of particles in suspension).

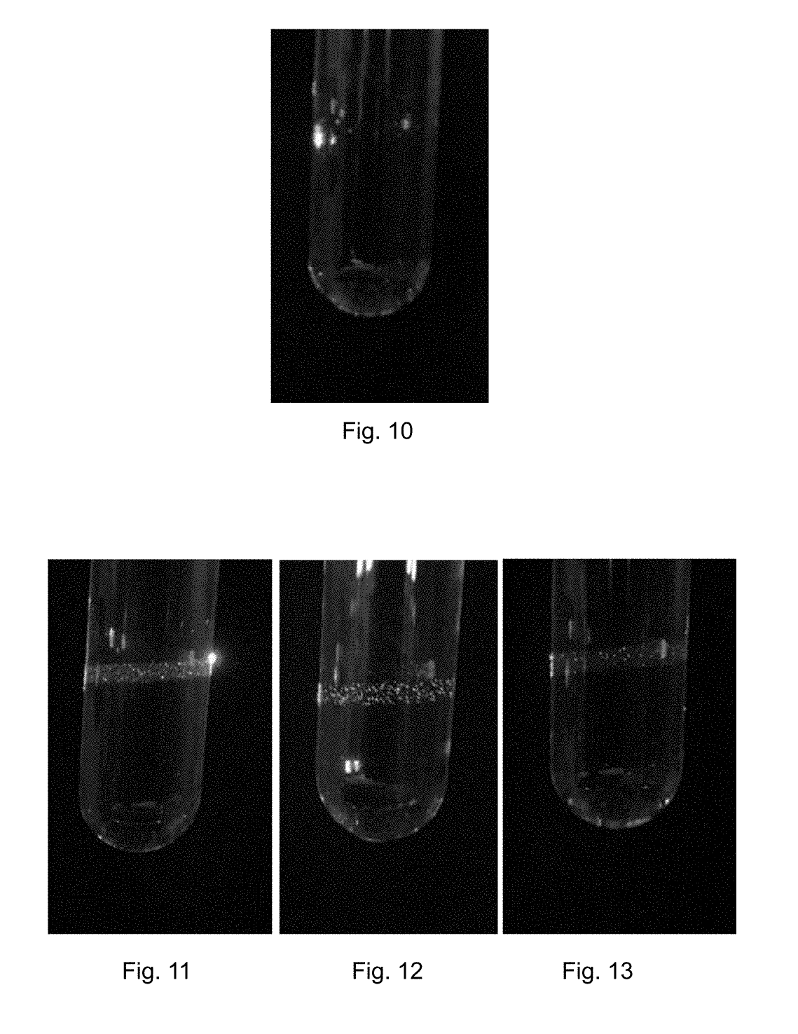

The results are shown in FIGS. 10 to 13. FIG. 10 represents the case without graphene and FIGS. 11 to 13 correspond to solutions with graphene. A laser beam can be clearly seen going through the test tube. This means that there are particles in suspension. “Bright spots” corresponding to larger particles can also be seen.

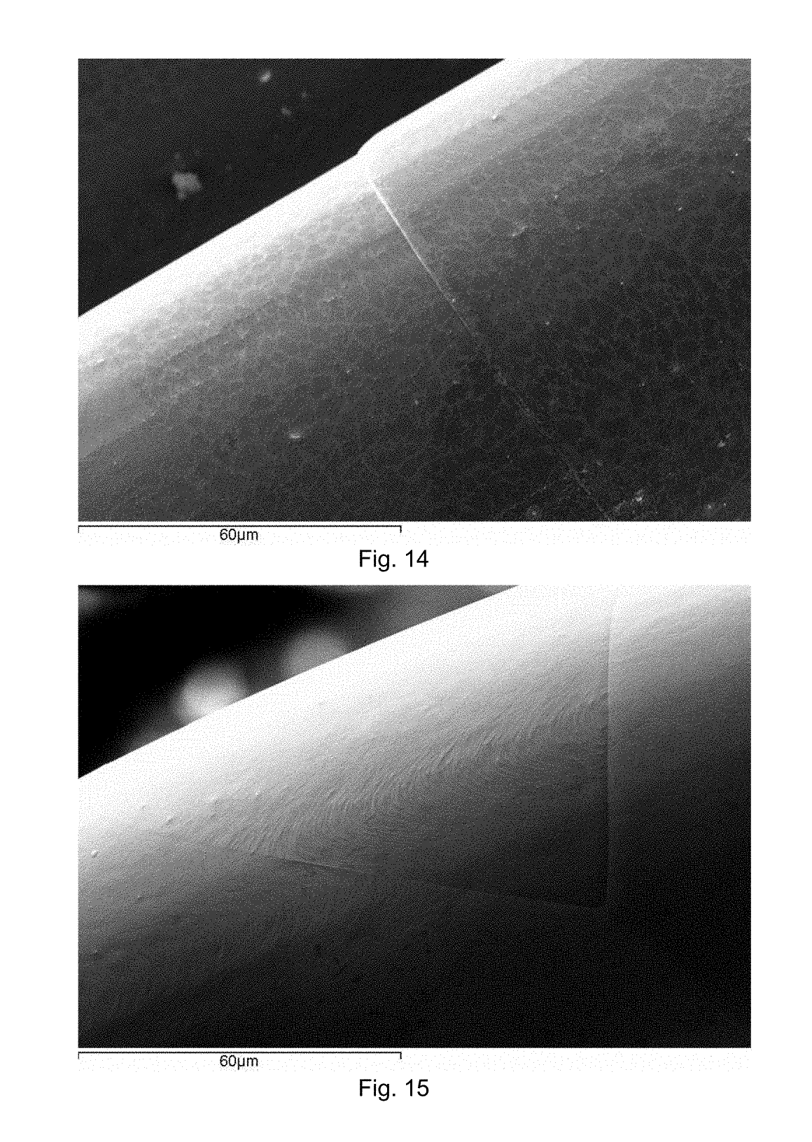

FIG. 14 shows a Cu wire on which graphene has been deposited under the following conditions:
10 minutes of reaction
10% methane (the rest being hydrogen)
1000° C.

Graphene was separated like in the preceding case but with 0.25 M NaOH as an electrolyte (conductivity of 24.8 mS). FIG. 15 shows the Cu wire after the separation step.

1. A method of producing a suspension of graphene particles, characterized in that it comprises the steps of:
[a] depositing carbon on a substrate by means of CVD, where graphene particles are formed on said substrate partially covering it,
[b] interrupting the deposition of carbon on said substrate before the surface of the substrate coated with graphene is more than 85% of the total surface of the substrate, preferably before the surface of the substrate coated with graphene is more than 75% of the total surface of the substrate,
[c] immersing said substrate in a liquid, and
[d] separating said graphene particles from said substrate such that they are suspended in said liquid.

2. The method according to claim 1, characterized in that said substrate is a metal substrate, preferably a Cu substrate.

3. The method according to claim 1, characterized in that said substrate has a non-metal base and a metal coating, said coating preferably being a Cu coating.

4. The method according to claim 2, characterized in that said Cu is electropolished Cu.

5. The method according to claim 1, characterized in that said substrate is formed by a sheet.

6. The method according to claim 1, characterized in that said substrate is formed by a wire.

7. The method according to claim 1, characterized in that said substrate is formed by foam.

8. The method according to claim 1, characterized in that said substrate is formed by a plurality of particles.

9. The method according to claim 1, characterized in that the Cu is dissolved in said step [d], such that the graphene particles on the Cu are suspended in said liquid.

10. The method according to claim 1, characterized in that an electrolysis causing the detachment of hydrogen on the surface of the Cu is performed in said step [d], such that the graphene particles on the Cu are suspended in said liquid.

11. The method according to claim 1, characterized in that the interruption in said step [b] takes place before more than 30% of the graphene particles are polycrystalline particles, preferably before more than 20% of the graphene particles are polycrystalline particles.

12. The method according to claim 1, characterized in that the interruption in said step [b] takes place before more than 50% of the generated graphene surface is a multilayer surface.

13. The method according to claim 1, characterized in that the interruption in said step [b] takes place before said particles have completely coalesced.

14. The method according to claim 1, characterized in that it comprises a step of recrystallizing said substrate or said metal coating before said deposition step.

15. The method according to claim 1, characterized in that it comprises a step of reducing surface oxides before the deposition step.

16. The method according to claim 1, characterized in that said deposition step is performed in a CH₄ and H₂ atmosphere, with a CH₄ content comprised between 10% and 60%, for a time comprised between 1 and 60 minutes, at a pressure comprised between 0.01 and 1000 mbar, preferably between 0.01 and 10 mbar, and at a temperature comprised between 900° C. and 1060° C.

17. The method according to claim 1, characterized in that said step [b] of interrupting the deposition comprises a cooling step in which the partially coated substrate is cooled at a temperature less than 600° C. in a time less than 30 minutes, and preferably in a time less than 120 seconds.

18. A suspension of graphene particles, characterized in that at least 50% of said graphene particles are monolayer particles, and preferably at least 70% of said graphene particles are monolayer particles.

19. The suspension according to claim 18, characterized in that the mean size of said particles is greater than 700 nm.
